(19) United States
(12) Patent Application Publication
(10) Pub. No.: US 2026/0293235 A1
(43) Pub. Date: Sep. 24, 2026

(54) SEMICONDUCTOR DEVICE AND FABRICATION METHOD THEREOF

(71) Applicant: UNITED MICROELECTRONICS CORP., Hsin-chu City (TW)

(72) Inventors: Chih-Hsin Chang, Hsinchu County (TW); Hsueh-Chun Hsiao, Hsinchu County (TW)

(73) Assignee: UNITED MICROELECTRONICS CORP., Hsin-chu City (TW)

(21) Appl. No.: 19/178,890

(22) Filed: Apr. 15, 2025

(30) Foreign Application Priority Data
Mar. 21, 2025 (TW) 114110691

(51) Int. Cl. H10D 62/10; H10D 30/01; H10D 30/60; H10D 62/13; H10D 64/62; H10D 64/66

(52) U.S. Cl. CPC H10D 62/116; H10D 30/0212; H10D 30/027; H10D 30/60; H10D 62/104; H10D 62/151; H10D 64/62; H10D 64/668

(57) ABSTRACT

A device and method are described for forming a grounded gate NMOS(GGMNOS) device used to provide protection against electrostatic discharge (ESD) in an integrated circuit (IC). The device is achieved by adding n-wells below the source and drain regions. By tailoring the dopant concentration profiles of the p-well and n-wells provided in the fabrication process, peak dopant concentrations are moved below the silicon surface. This moves ESD conduction deeper into the IC where thermal conductivity is improved, thereby avoiding thermal damage occurring with surface conduction. The device does not require a salicidation block or additional implantation and uses standard NMOS fabrication processing steps, making it advantageous over prior art solutions.

### BACKGROUND OF THE INVENTION

### 1. Field of the Invention

The present invention relates to the technical field of semiconductors, and particularly relates to a semiconductor device and its manufacturing method.

### 2. Description of the Prior Art

Embedded flash memory is a type of non-volatile memory that is directly integrated into an integrated circuit (IC) chip. Existing medium voltage (MV) components in embedded flash memory devices face the problem of poor breakdown voltage uniformity, thus there is a need for further improvement.

### SUMMARY OF THE INVENTION

It is one objective of the present invention to provide an improved semiconductor device and a method for manufacturing the same, so as to overcome the aforementioned deficiencies or shortcomings of the prior art.

One aspect of the invention provides a semiconductor device including a substrate having an active area and an isolation region surrounding the active area; a source region and a drain region disposed in the active area, defining a channel region therebetween; a gate disposed over the channel region; a gate dielectric layer disposed between the gate and the channel region; and a ring-shaped salicide block layer disposed along a perimeter of the active area.

According to some embodiments, a ring-shaped divot is formed at an interface between the isolation region and the active area, wherein the ring-shaped salicide block layer overlaps the ring-shaped divot.

According to some embodiments, the ring-shaped salicide block layer fully covers the ring-shaped divot and extends into a peripheral portion of the active area adjacent to the ring-shaped divot.

According to some embodiments, the peripheral portion of the active area has a width ranging from 0 to 0.1 micrometers.

According to some embodiments, the ring-shaped salicide block layer has a width ranging from 0.2 to 0.4 micrometers.

According to some embodiments, the ring-shaped salicide block layer comprises silicon oxide, silicon nitride, or a combination thereof.

According to some embodiments, the semiconductor device further includes a source silicide layer disposed on the source region not covered by the ring-shaped salicide block layer; a drain silicide layer disposed on the drain region not covered by the ring-shaped salicide block layer; and a gate silicide layer disposed on the gate not covered by the ring-shaped salicide block layer.

According to some embodiments, the source silicide layer and the drain silicide layer are not in direct contact with the isolation region.

According to some embodiments, the semiconductor device further includes a spacer disposed on a sidewall of the gate, wherein the ring-shaped salicide block layer extends onto the spacer and the gate.

According to some embodiments, the spacer comprises silicon nitride.

Another aspect of the invention provides a method for forming a semiconductor device including the steps of: providing a substrate having an active area and an isolation region surrounding the active area; forming a source region and a drain region in the active area, defining a channel region therebetween; forming a gate over the channel region; forming a gate dielectric layer between the gate and the channel region; and forming a ring-shaped salicide block layer along a perimeter of the active area.

According to some embodiments, a ring-shaped divot is formed at an interface between the isolation region and the active area, wherein the ring-shaped salicide block layer overlaps the ring-shaped divot.

According to some embodiments, the ring-shaped salicide block layer fully covers the ring-shaped divot and extends into a peripheral portion of the active area adjacent to the ring-shaped divot.

According to some embodiments, the peripheral portion of the active area has a width ranging from 0 to 0.1 micrometers.

According to some embodiments, the ring-shaped salicide block layer has a width ranging from 0.2 to 0.4 micrometers.

According to some embodiments, the ring-shaped salicide block layer comprises silicon oxide, silicon nitride, or a combination thereof.

According to some embodiments, the method further includes the steps of: forming a source silicide layer on the source region not covered by the ring-shaped salicide block layer; forming a drain silicide layer on the drain region not covered by the ring-shaped salicide block layer; and forming a gate silicide layer on the gate not covered by the ring-shaped salicide block layer.

According to some embodiments, the source silicide layer and the drain silicide layer are not in direct contact with the isolation region.

According to some embodiments, the method further includes the step of: forming a spacer on a sidewall of the gate, wherein the ring-shaped salicide block layer extends onto the spacer and the gate.

According to some embodiments, the spacer comprises silicon nitride.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of the semiconductor device according to an embodiment of the present invention.

FIG. 2 is a schematic cross-sectional view taken along line I-I′ in FIG. 1.

FIG. 3 is a schematic cross-sectional view taken along line II-II′ in FIG. 1.

FIG. 4 illustrates the manufacturing method flow of the semiconductor device.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

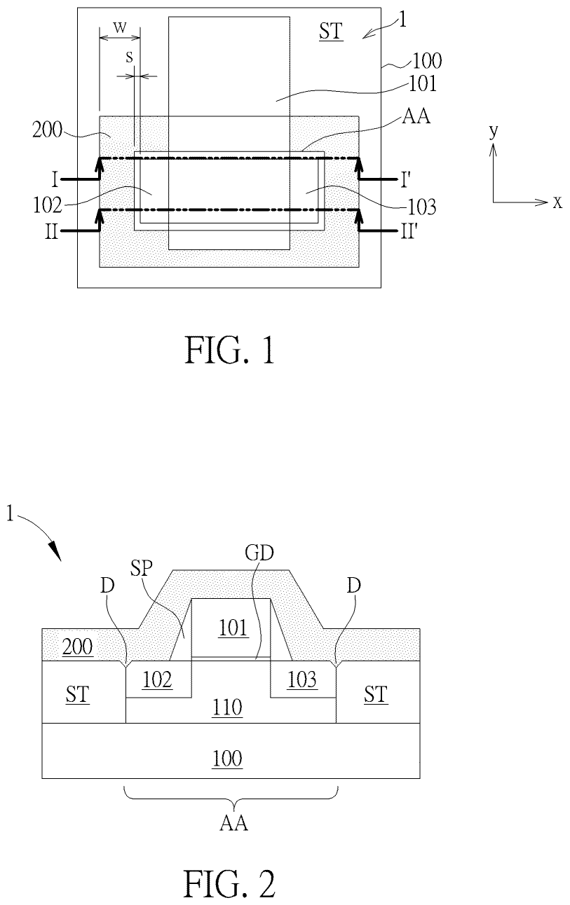

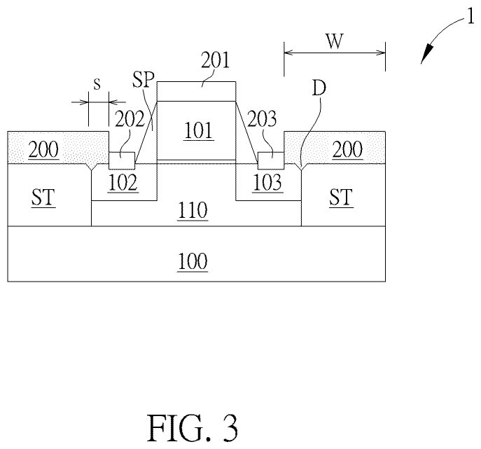

Please refer to FIGS. 1-3, wherein FIG. 1 is a schematic top view of the semiconductor device according to an embodiment of the present invention, FIG. 2 is a schematic cross-sectional view taken along line I-I′ in FIG. 1, and FIG. 3 is a schematic cross-sectional view taken along line II-II′ in FIG. 1. As shown in FIGS. 1-3, the semiconductor device 1 includes a substrate 100 having an active area AA and an isolation region ST surrounding the active area AA. According to an embodiment of the present invention, for example, the substrate 100 may be a P-type silicon substrate, but is not limited thereto. According to an embodiment of the present invention, for example, the isolation region ST may be a shallow trench isolation region. According to an embodiment of the present invention, the semiconductor device 1 may further include a high-voltage P-well 110 disposed in the substrate 100.

According to an embodiment of the present invention, the semiconductor device 1 further includes a gate 101 extending along the reference y-axis direction in FIG. 1, which crosses the active area AA. According to an embodiment of the present invention, the gate 101 is, for example, a polysilicon gate, but is not limited thereto.

According to an embodiment of the present invention, the semiconductor device 1 further includes a source region 102 and a drain region 103 disposed in the active area AA, defining a channel region CH therebetween. According to an embodiment of the present invention, the gate 101 is disposed above the channel region CH. According to an embodiment of the present invention, the semiconductor device 1 further includes a gate dielectric layer GD disposed between the gate 101 and the channel region CH. According to an embodiment of the present invention, the gate dielectric layer GD is, for example, a silicon dioxide layer, but is not limited thereto.

According to an embodiment of the present invention, the semiconductor device 1 further includes a ring-shaped salicide block layer 200 disposed along the periphery of the active area AA. According to an embodiment of the present invention, as shown in FIGS. 2-3, a ring-shaped divot D is formed at the interface between the isolation region ST and the active area AA, wherein the ring-shaped salicide block layer 200 overlaps the ring-shaped divot D.

According to an embodiment of the present invention, the width w of the ring-shaped salicide block layer 200 is, for example, in the range of 0.2 to 0.4 micrometers. According to an embodiment of the present invention, the ring-shaped salicide block layer 200 is made of, for example, silicon oxide, silicon nitride, or a combination thereof.

According to an embodiment of the present invention, the ring-shaped salicide block layer 200 completely covers the ring-shaped divot D and extends to a peripheral portion of the active area AA adjacent to the ring-shaped divot D. According to an embodiment of the present invention, the width s of the peripheral portion of the active area AA overlapping with the ring-shaped salicide block layer 200 is in the range of 0 to 0.1 micrometers.

According to an embodiment of the present invention, as shown in FIG. 3, the semiconductor device 1 further includes a source silicide layer 202 disposed on the source region 102 not covered by the ring-shaped salicide block layer 200, a drain silicide layer 203 disposed on the drain region 103 not covered by the ring-shaped salicide block layer 200, and a gate silicide layer 201 disposed on the gate 101 not covered by the ring-shaped salicide block layer 200.

According to an embodiment of the present invention, the source silicide layer 202 and the drain silicide layer 203 are in direct contact with the ring-shaped salicide block layer 200 but do not directly contact the isolation region ST, which can effectively improve the breakdown voltage uniformity of medium voltage (MV) components in embedded flash memory devices.

According to an embodiment of the present invention, as shown in FIGS. 2-3, the semiconductor device 1 further includes spacers SP disposed on the sidewalls of the gate 101, wherein, as shown in FIG. 2, the ring-shaped salicide block layer 200 extends onto the spacers SP and the gate 101. According to an embodiment of the present invention, the spacers SP may be made of, for example, silicon nitride, but are not limited thereto.

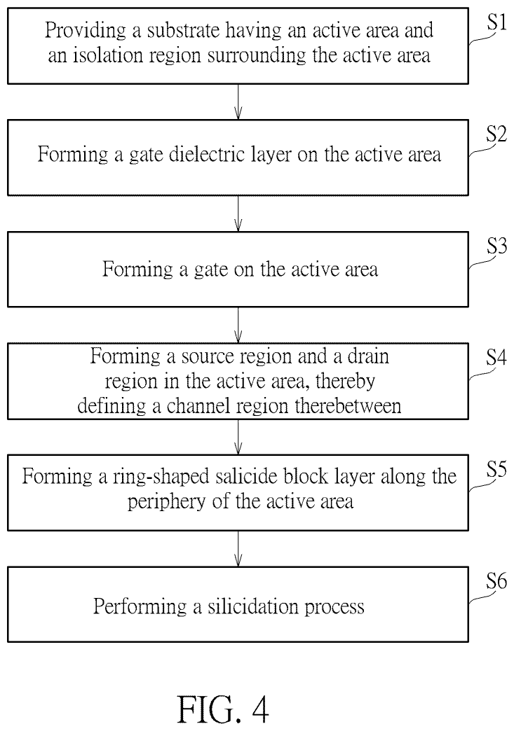

Please also refer to FIG. 4, which illustrates the manufacturing method flow of the semiconductor device. As shown in FIGS. 1 to 4, first, step S1 is performed to provide a substrate 100 having an active area AA and an isolation region ST surrounding the active area AA. According to an embodiment of the present invention, for example, the substrate 100 may be a P-type silicon substrate, but is not limited thereto. According to an embodiment of the present invention, for example, the isolation region ST may be formed using a shallow trench isolation process.

According to an embodiment of the present invention, the semiconductor device 1 may further include a high-voltage P-well 110 disposed in the substrate 100. According to an embodiment of the present invention, as shown in FIGS. 2-3, a ring-shaped divot D is formed at the interface between the isolation region ST and the active area AA.

Next, step S2 in FIG. 4 is performed, involving an oxidation process or a deposition process to form a gate dielectric layer GD on the active area AA. According to an embodiment of the present invention, the gate dielectric layer GD is, for example, a silicon dioxide layer, but is not limited thereto.

Next, step S3 in FIG. 4 is performed to form the gate 101 above the gate dielectric layer GD. According to an embodiment of the present invention, as shown in FIG. 1, the gate 101 extends along the reference y-axis direction in FIG. 1, crossing the active area AA. According to an embodiment of the present invention, the gate 101 is, for example, a polysilicon gate, but is not limited thereto. According to an embodiment of the present invention, as shown in FIGS. 2-3, spacers SP are formed on the sidewalls of the gate 101. According to an embodiment of the present invention, the spacers SP may be made of, for example, silicon nitride.

Next, step S4 in FIG. 4 is performed, using a photolithography process and an ion implantation process to form the source region 102 and the drain region 103 in the active area AA, defining the channel region CH therebetween.

Next, step S5 in FIG. 4 is performed, using a deposition process, a photolithography process, and an etching process to form the ring-shaped salicide block layer 200 along the periphery of the active area AA. According to an embodiment of the present invention, as shown in FIGS. 2-3, the ring-shaped salicide block layer 200 is formed along the ring-shaped divot D at the interface between the isolation region ST and the active area AA, wherein the ring-shaped salicide block layer 200 overlaps the ring-shaped divot D.

According to an embodiment of the present invention, as shown in FIGS. 2-3, the ring-shaped salicide block layer 200 completely covers the ring-shaped divot D and extends to a peripheral portion of the active area AA adjacent to the ring-shaped divot D. According to an embodiment of the present invention, the ring-shaped salicide block layer 200 may be made of, for example, silicon oxide, silicon nitride, or a combination thereof.

According to an embodiment of the present invention, the width s of the peripheral portion of the active area AA overlapping with the ring-shaped salicide block layer 200 is in the range of 0 to 0.1 micrometers. According to an embodiment of the present invention, the width w of the ring-shaped salicide block layer 200 is in the range of 0.2 to 0.4 micrometers.

Next, step S6 in FIG. 4 is performed, involving a metal silicidation process to form a source silicide layer 202 on the source region 102 not covered by the ring-shaped salicide block layer 200, a drain silicide layer 203 on the drain region 103 not covered by the ring-shaped salicide block layer 200, and a gate silicide layer 201 on the gate 101 not covered by the ring-shaped salicide block layer 200.

According to an embodiment of the present invention, as shown in FIG. 3, the source silicide layer 202 and the drain silicide layer 203 are not in direct contact with the isolation region ST. According to an embodiment of the present invention, as shown in FIG. 2, the ring-shaped salicide block layer 200 extends onto the spacers SP and the gate 101.

Those skilled in the art will readily observe that numerous modifications and alterations of the device and method may be made while retaining the teachings of the invention.

Accordingly, the above disclosure should be construed as limited only by the metes and bounds of the appended claims.

What is claimed is:

1. A semiconductor device, comprising:
a substrate having an active area and an isolation region surrounding the active area;
a source region and a drain region disposed in the active area, defining a channel region therebetween;
a gate disposed over the channel region;
a gate dielectric layer disposed between the gate and the channel region; and
a ring-shaped salicide block layer disposed along a perimeter of the active area.

2. The semiconductor device according to claim 1, wherein a ring-shaped divot is formed at an interface between the isolation region and the active area, wherein the ring-shaped salicide block layer overlaps the ring-shaped divot.

3. The semiconductor device according to claim 2, wherein the ring-shaped salicide block layer fully covers the ring-shaped divot and extends into a peripheral portion of the active area adjacent to the ring-shaped divot.

4. The semiconductor device according to claim 3, wherein the peripheral portion of the active area has a width ranging from 0 to 0.1 micrometers.

5. The semiconductor device according to claim 1, wherein the ring-shaped salicide block layer has a width ranging from 0.2 to 0.4 micrometers.

6. The semiconductor device according to claim 1, wherein the ring-shaped salicide block layer comprises silicon oxide, silicon nitride, or a combination thereof.

7. The semiconductor device according to claim 1 further comprising:
a source silicide layer disposed on the source region not covered by the ring-shaped salicide block layer;
a drain silicide layer disposed on the drain region not covered by the ring-shaped salicide block layer; and
a gate silicide layer disposed on the gate not covered by the ring-shaped salicide block layer.

8. The semiconductor device according to claim 7, wherein the source silicide layer and the drain silicide layer are not in direct contact with the isolation region.

9. The semiconductor device according to claim 1 further comprising:
a spacer disposed on a sidewall of the gate, wherein the ring-shaped salicide block layer extends onto the spacer and the gate.

10. The semiconductor device according to claim 9, wherein the spacer comprises silicon nitride.

11. A method for forming a semiconductor device, comprising:
providing a substrate having an active area and an isolation region surrounding the active area;
forming a source region and a drain region in the active area, defining a channel region therebetween;
forming a gate over the channel region;
forming a gate dielectric layer between the gate and the channel region; and
forming a ring-shaped salicide block layer along a perimeter of the active area.

12. The method according to claim 11, wherein a ring-shaped divot is formed at an interface between the isolation region and the active area, wherein the ring-shaped salicide block layer overlaps the ring-shaped divot.

13. The method according to claim 12, wherein the ring-shaped salicide block layer fully covers the ring-shaped divot and extends into a peripheral portion of the active area adjacent to the ring-shaped divot.

14. The method according to claim 13, wherein the peripheral portion of the active area has a width ranging from 0 to 0.1 micrometers.

15. The method according to claim 11, wherein the ring-shaped salicide block layer has a width ranging from 0.2 to 0.4 micrometers.

16. The method according to claim 11, wherein the ring-shaped salicide block layer comprises silicon oxide, silicon nitride, or a combination thereof.

17. The method according to claim 11 further comprising:
forming a source silicide layer on the source region not covered by the ring-shaped salicide block layer;
forming a drain silicide layer on the drain region not covered by the ring-shaped salicide block layer; and
forming a gate silicide layer on the gate not covered by the ring-shaped salicide block layer.

18. The method according to claim 17, wherein the source silicide layer and the drain silicide layer are not in direct contact with the isolation region.

19. The method according to claim 11 further comprising:
forming a spacer on a sidewall of the gate, wherein the ring-shaped salicide block layer extends onto the spacer and the gate.

20. The method according to claim 19, wherein the spacer comprises silicon nitride.
